(19) United States
(12) Patent Application Publication
(10) Pub. No.: US 2025/0355059 A1
(43) Pub. Date: Nov. 20, 2025

(54) TESTING DEVICE FOR SHORT CIRCUIT CONDITION AND RELATED METHODS

(71) Applicant: SELIMA PARTNERS, LLC, ORLANDO, FL (US)

(72) Inventors: STEVE IRELAND, ORLANDO, FL (US); AJAY SEQUEIRA, ORLANDO, FL (US)

(21) Appl. No.: 19/207,698

(22) Filed: May 14, 2025

Related U.S. Application Data
(60) Provisional application No. 63/647,397, filed on May 14, 2024.

(51) Int. Cl. G01R 31/52; G01R 31/08

(52) U.S. Cl. CPC G01R 31/52; G01R 31/08

(57) ABSTRACT

A testing device is for detecting a short circuit condition in a DUT. The testing device includes a drive electrode to be coupled to the DUT, a sensing electrode to be coupled to the DUT, and a testing probe to be selectively coupled to locations on the DUT. The testing device also includes a controller unit coupled to the drive electrode, the sensing electrode, and the testing probe. The controller unit is configured to generate an AC current source signal at the drive electrode, at the testing probe, detect voltage signals for the locations on the DUT, and determine a given location on the DUT to be adjacent to the short circuit condition based upon voltage signals for the locations on the DUT.

### RELATED APPLICATION

This application is based upon prior filed copending Application No. 63/647,397 filed May 14, 2024, the entire subject matter of which is incorporated herein by reference in its entirety.

### TECHNICAL FIELD

The present disclosure relates to the field of testing devices, and, more particularly, to a testing device for short conditions and related methods.

### BACKGROUND

Testing devices are commonly used in the electronic industry. In one common application, circuit board devices are flagged for an operational error due to a potential hardware defect, and then tested to locate potential faults for correction. Helpfully, if a fault is located and cured, the circuit board device can be returned to service, which prevents waste of the circuit board device.

Typical testing devices are manually operated, and testing is location specific on the circuit board device being tested. In other words, the user moves a testing probe on the circuit board device looking for the fault, which is a proverbial needle in a haystack. Because of this, as circuit board devices have become more complex, it has become impractical to test these devices for faults, let alone locate the fault.

### SUMMARY

Generally, a testing device is for detecting a short circuit condition in a device under test (DUT). The testing device comprises at least one drive electrode to be coupled to the DUT, at least one sensing electrode to be coupled to the DUT, and a testing probe to be selectively coupled to a plurality of locations on the DUT. The testing device also includes a controller unit coupled to the at least one drive electrode, the at least one sensing electrode, and the testing probe. The controller unit is configured to generate an alternating current (AC) current source signal at the at least one drive electrode, and at the testing probe, detect a plurality of voltage signals for the plurality of locations on the DUT. The controller unit is configured to determine a given location on the DUT to be adjacent to the short circuit condition based upon plurality of voltage signals for the plurality of locations on the DUT.

In particular, the controller unit may be configured to determine the given location on the DUT when a respective voltage signal has a threshold signal value in the plurality of voltage signals. The controller unit may be configured to generate an indication based upon a respective voltage signal in the plurality of voltage signals.

Also, the controller unit may be configured to set a current of the AC current source signal based upon a resistance between the at least one drive electrode and the at least one sensing electrode. The controller unit may be configured to set a current of the AC current source signal so that a voltage drop across the at least one drive electrode and the at least one sensing electrode is less than 0.1 Volt.

For example, the controller unit may be configured to set a current of the AC current source signal in a range of 0.2-20 mA. The AC current source signal may have a frequency in a range of 1-3 Hz. The at least one drive electrode may comprise a plurality of drive electrodes, and the at least one sensing electrode may comprise a plurality of sensing electrodes. The DUT may comprise a multi-layer circuit board. The at least one drive electrode may be coupled to a first plane of the DUT, and the at least one sensing electrode may be coupled to a reference plane of the DUT.

Another aspect is directed to a method of detecting a short circuit condition in a DUT. The method comprises coupling at least one drive electrode to the DUT, coupling at least one sensing electrode to the DUT, and selectively coupling a testing probe to a plurality of locations on the DUT. The method also includes operating a controller unit coupled to the at least one drive electrode, the at least one sensing electrode, and the testing probe. The controller unit is configured to generate an AC current source signal at the at least one drive electrode, and at the testing probe, detect a plurality of voltage signals for the plurality of locations on the DUT. The controller unit is configured to determine a given location on the DUT to be adjacent to the short circuit condition based upon plurality of voltage signals for the plurality of locations on the DUT.

### BRIEF DESCRIPTION OF THE DRAWINGS

FIG. 1 is a schematic diagram of a testing device, according to an example embodiment of the present disclosure.

FIG. 2 is a schematic diagram of the testing device from FIG. 1 during a testing procedure.

FIG. 3 is a schematic diagram of the DUT being tested by the testing device of FIG. 1.

FIG. 4 is a flowchart of a method for testing using the testing device of FIG. 1.

### DETAILED DESCRIPTION

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout, and base 100 reference numerals are used to indicate similar elements in alternative embodiments.

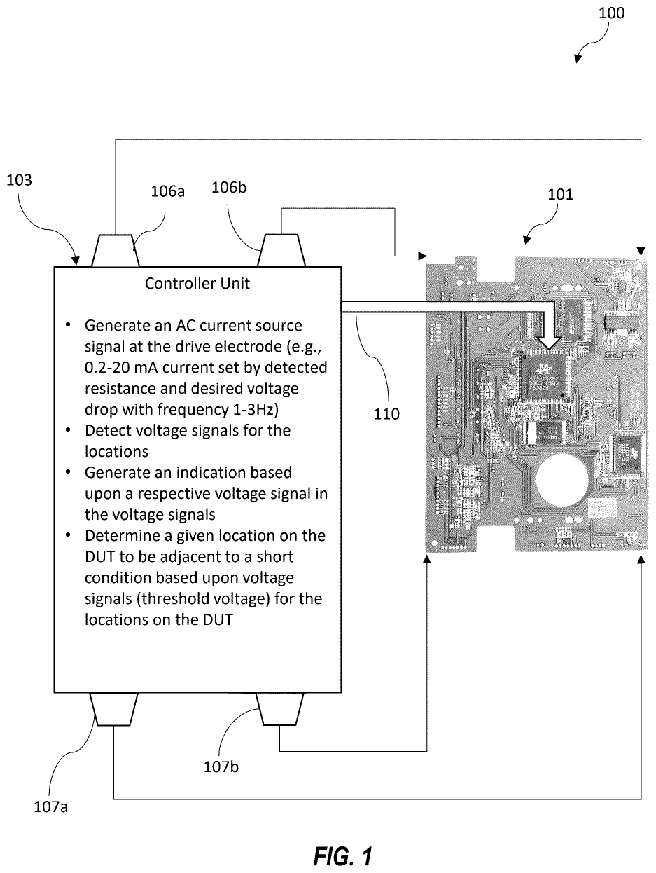

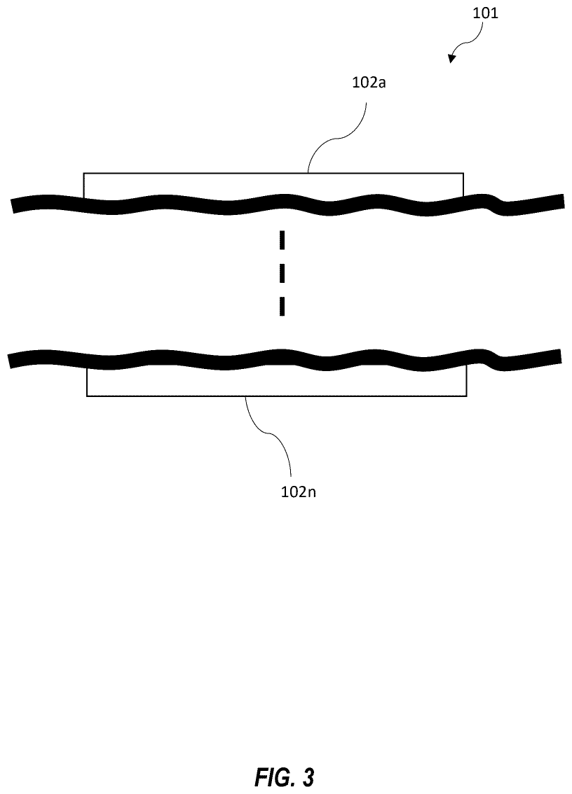

Referring initially to FIGS. 1-3, a testing device 100 according to the present disclosure is now described. The testing device 100 is for detecting a short circuit condition in a DUT 101. It should be appreciated that the DUT 101 is illustratively a multi-layer circuit board device having a plurality of planes 102a-102n, for example, a power supply plane 102a (first plane), a reference voltage plane (second plane or ground plane) 102n, a signal plane, and a routing layer plane. Of course, it should be appreciated that the testing device 100 can be applied to a wide variety of electronic devices.

The testing device 100 illustratively includes a controller unit 103 comprising a processor 104, and an indicator 105 coupled to the processor. The indicator 105 may comprise one or more of an audio indicator (e.g., speaker, piezoelectric alarm), and a visual indicator (e.g., an LED device, a display).

The testing device 100 illustratively includes a plurality of drive electrodes 106a-106b coupled to the controller unit 103 and to be coupled to the DUT 101, and a plurality of sensing electrodes 107a-107b coupled to the controller unit and to be coupled to the DUT. The testing device 100 illustratively includes a testing probe 110 coupled to the controller unit 103 and to be selectively coupled to a plurality of locations 111a-111c on the DUT 101 by a user. In some embodiments, the plurality of drive electrodes 106a-106b may be reduced to a single drive electrode, and the plurality of sensing electrodes 107a-107b can similarly be reduced to a single sensing electrode.

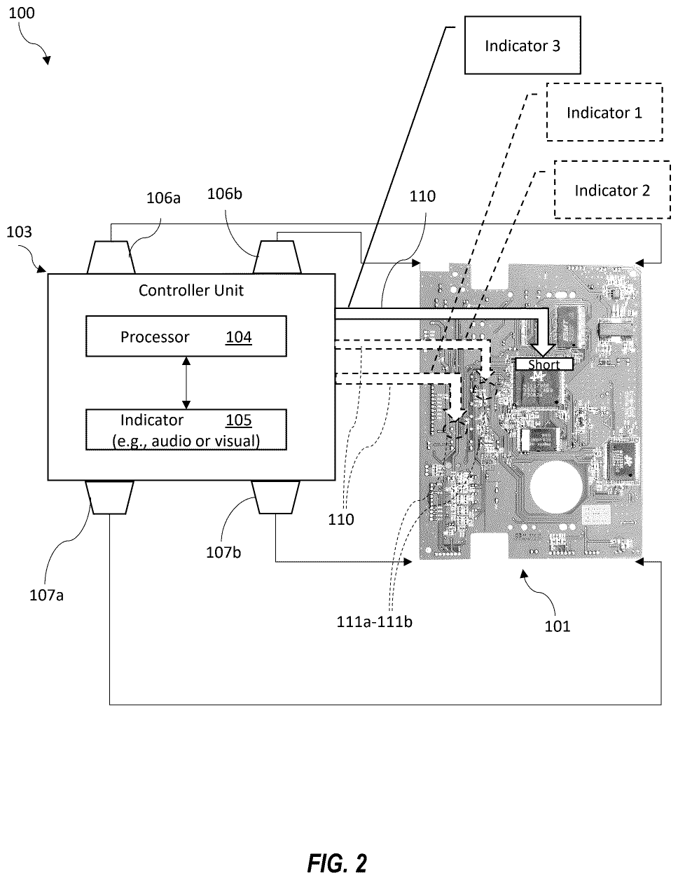

As will be appreciated, during testing, the user of the testing device 100 will couple the plurality of drive electrodes 106a-106b to the first plane 102a (e.g., the power plane) of the DUT 101, and the plurality of sensing electrodes 107a-107b to the second plane 102n (e.g., ground plane) of the DUT. After these coupling steps, the user would power the controller unit 103 and position the testing probe 110 on plurality of locations 111a-111c on the DUT 101 in search of the short circuit condition. This repositioning is shown with dashed boxes in FIG. 2.

The controller unit 103 is configured to generate an AC current source signal at one or more of the plurality of drive electrodes 106a-106b. In particular, the controller unit 103 is configured to set a current of the AC current source signal based upon a resistance between one or more of the plurality of one drive electrodes 106a-106b and one or more of the plurality of sensing electrodes 107-107b. The controller unit 103 is configured to set a current of the AC current source signal so that a voltage drop across the one or more of the plurality of one drive electrodes 106a-106b and the one or more of the plurality of sensing electrodes 107-107b is less than 0.1 Volt. Helpfully, this may prevent untended activation of circuit components on the DUT 101. For example, the controller unit 103 is configured to set a current of the AC current source signal in a range of 0.2-20 mA, and set a frequency of the AC current source signal in a range of 1-3 Hz. In some embodiments, the frequency of the AC current source signal may comprise 2 Hz.

As perhaps best seen in FIG. 2, as the user positions the testing probe 110 on plurality of locations 111a-111c on the DUT 101, the controller unit 103 is configured to, at the testing probe, detect a plurality of voltage signals for the plurality of locations on the DUT. The controller unit 103 is configured to determine a given location 111c on the DUT 101 to be adjacent to the short circuit condition based upon plurality of voltage signals for the plurality of locations 111a-111c on the DUT.

More specifically, the controller unit 103 is configured to activate the indicator 105 to generate an indication based upon a respective voltage signal in the plurality of voltage signals. In particular, the controller unit 103 is configured to measure a precise voltage/signal level for each voltage signal in the plurality of voltage signals. In some embodiments, the detected signal may comprise a millivolt or nanovolt signal. The indication is intended to guide the user in the positioning of the testing probe 110 on the DUT 101. As the detected voltage/signal level for each voltage signal decreases (i.e., approaching the short circuit condition), the indication comprises a positive indication to guide the user to the location adjacent the short circuit condition. For instance, in the illustrated example, indicator 2 would be greater in value (i.e., louder for audio indicators, brighter for visual indicators) than indicator 1, and indicator 3 would be greater in value than indicator 2. As the detected voltage/signal level for each voltage signal increases (i.e., moving away from the short circuit condition), the indication comprises a negative indication to guide the user in the opposite direction and to the location adjacent the short circuit condition (i.e., less loud for audio indicators, darker for visual indicators). Once the detected voltage/signal level approaches zero or is zero (i.e., the respective voltage signal has a threshold signal value (minimum signal value)), the indication comprises a termination indication to inform the user that the given location 111c on the DUT 101 is adjacent to the short circuit condition.

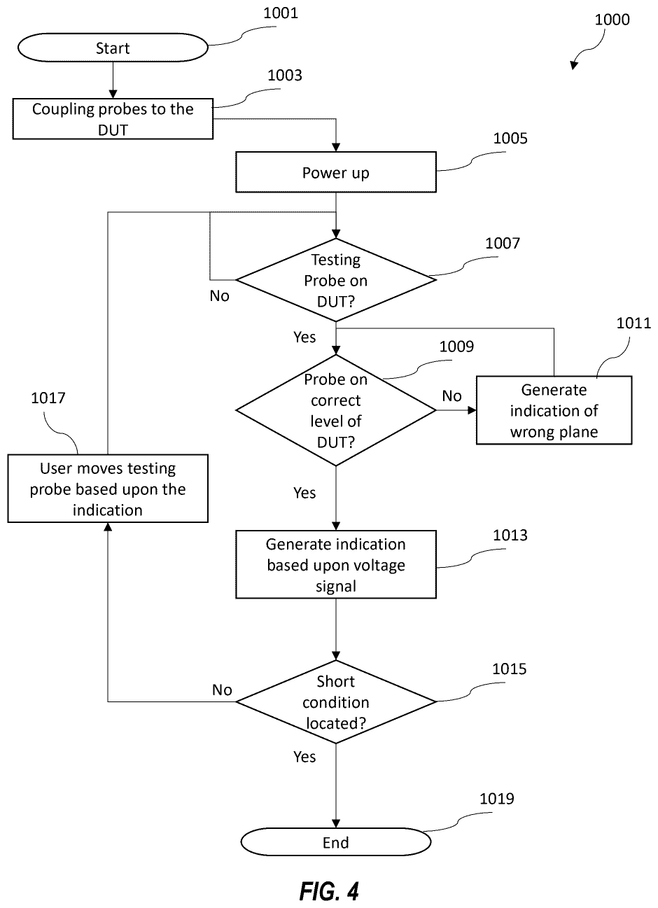

Referring now additionally to FIG. 4, a method of detecting a short circuit condition in a DUT 101 is now described with reference to a flowchart 1000, which begins at Block 1001. The method comprises coupling a plurality of one drive electrodes 106a-106b to the DUT 101, coupling a plurality of sensing electrodes 107-107b to the DUT, and powering the testing device 100. (Blocks 1003, 1005). The method comprises selectively coupling a testing probe 110 to a plurality of locations 111a-111c on the DUT 101. In particular, at Block 1007, the controller unit 103 is configured to detect whether the testing probe 110 is contacting the DUT 101 by determining a resistance between the testing probe 110 and one or more of the plurality of one drive electrodes 106a-106b and/or one or more of the plurality of sensing electrodes 107-107b. This functionality may be based upon an on-board ohmmeter within the controller unit 103.

At Block 1009, the method illustratively comprises determining whether the testing probe 110 is on a correct plane of the DUT 101. Once the testing probe 110 is contacting the DUT 101, a voltage measurement will be taken and compared to a threshold voltage, which is 20 mV, for example. The absolute value of the measurement will be used for comparison since the voltage reading can be negative. If it is negative, then that means the testing probe 110 is on the correct plane. If the absolute value of the measurement is less than the 20 mV, then the controller unit 103 is configured to adjust one or more of drive electrode volage and/or voltmeter gain and measure again. The controller unit 103 is configured to check if the voltage measurement is positive or negative. If the voltage reading is positive, then this indicates that the testing probe 110 is on the wrong plane and will communicate that to the user. (Block 1011). Thus, the user will have to start at another location on the DUT 101. Otherwise, if the voltage measurement is negative, then the testing probe 110 is on the correct plane.

The method also includes operating a controller unit 103 coupled to the plurality of drive electrodes 106a-106b, the plurality of sensing electrodes 107-107b, and the testing probe 110. The controller unit is configured to generate an AC current source signal at one or more of the plurality of one drive electrodes 106a-106b, and at the testing probe 110, detect a plurality of voltage signals for the plurality of locations 111a-111c on the DUT 101. The method illustratively includes generating an indication of proximity to the short circuit condition based upon a current location of the testing probe 110. (Blocks 1013). As detailed hereinabove, the method illustratively comprises determining a given location on the DUT 101 to be adjacent to a short circuit condition based upon plurality of voltage signals for the plurality of locations 111a-111c on the DUT. (Blocks 1015, 1017). The method ends at Block 1019 with the detection of the short circuit condition location.

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A testing device for detecting a short circuit condition in a device under test (DUT), the testing device comprising:
at least one drive electrode to be coupled to the DUT;
at least one sensing electrode to be coupled to the DUT;
a testing probe to be selectively coupled to a plurality of locations on the DUT; and
a controller unit coupled to the at least one drive electrode, the at least one sensing electrode, and the testing probe, the controller unit configured to
generate an alternating current (AC) current source signal at the at least one drive electrode,
at the testing probe, detect a plurality of voltage signals for the plurality of locations on the DUT, and
determine a given location on the DUT to be adjacent to the short circuit condition based upon plurality of voltage signals for the plurality of locations on the DUT.

2. The testing device of claim 1 wherein the controller unit is configured to determine the given location on the DUT when a respective voltage signal has a threshold signal value in the plurality of voltage signals.

3. The testing device of claim 1 wherein the controller unit is configured to generate an indication based upon a respective voltage signal in the plurality of voltage signals.

4. The testing device of claim 1 wherein the controller unit is configured to set a current of the AC current source signal based upon a resistance between the at least one drive electrode and the at least one sensing electrode.

5. The testing device of claim 1 wherein the controller unit is configured to set a current of the AC current source signal so that a voltage drop across the at least one drive electrode and the at least one sensing electrode is less than 0.1 Volt.

6. The testing device of claim 1 wherein the controller unit is configured to set a current of the AC current source signal in a range of 0.2-20 mA.

7. The testing device of claim 1 wherein the AC current source signal has a frequency in a range of 1-3 Hz.

8. The testing device of claim 1 wherein the at least one drive electrode comprises a plurality of drive electrodes; and wherein the at least one sensing electrode comprises a plurality of sensing electrodes.

9. The testing device of claim 1 wherein the DUT comprises a multi-layer circuit board; wherein the at least one drive electrode is to be coupled to a first plane of the DUT;
and wherein the at least one sensing electrode is to be coupled to a reference plane of the DUT.

10. A testing device for detecting a short circuit condition in a device under test (DUT), the testing device comprising:
at least one drive electrode to be coupled to the DUT;
at least one sensing electrode to be coupled to the DUT;
a testing probe to be selectively coupled to a plurality of locations on the DUT; and
a controller unit coupled to the at least one drive electrode, the at least one sensing electrode, and the testing probe, the controller unit configured to
generate an alternating current (AC) current source signal at the at least one drive electrode, the AC current source signal having a frequency in a range of 1-3 Hz,
at the testing probe, detect a plurality of voltage signals for the plurality of locations on the DUT,
generate an indication based upon a respective voltage signal in the plurality of voltage signals, and
determine a given location on the DUT to be adjacent to the short circuit condition based upon plurality of voltage signals for the plurality of locations on the DUT when a respective voltage signal has a threshold signal value in the plurality of voltage signals.

11. The testing device of claim 10 wherein the controller unit is configured to set a current of the AC current source signal based upon a resistance between the at least one drive electrode and the at least one sensing electrode.

12. The testing device of claim 10 wherein the controller unit is configured to set a current of the AC current source signal so that a voltage drop across the at least one drive electrode and the at least one sensing electrode is less than 0.1 Volt.

13. The testing device of claim 10 wherein the controller unit is configured to set a current of the AC current source signal in a range of 0.2-20 mA.

14. The testing device of claim 10 wherein the at least one drive electrode comprises a plurality of drive electrodes; and wherein the at least one sensing electrode comprises a plurality of sensing electrodes.

15. The testing device of claim 10 wherein the DUT comprises a multi-layer circuit board; wherein the at least one drive electrode is to be coupled to a first plane of the DUT; and wherein the at least one sensing electrode is to be coupled to a reference plane of the DUT.

16. A method of detecting a short circuit condition in a device under test (DUT), the method comprising:
coupling at least one drive electrode to the DUT;
coupling at least one sensing electrode to the DUT;
selectively coupling a testing probe to a plurality of locations on the DUT; and
operating a controller unit coupled to the at least one drive electrode, the at least one sensing electrode, and the testing probe, the controller unit configured to
generate an alternating current (AC) current source signal at the at least one drive electrode,
at the testing probe, detect a plurality of voltage signals for the plurality of locations on the DUT, and
determine a given location on the DUT to be adjacent to the short circuit condition based upon plurality of voltage signals for the plurality of locations on the DUT.

17. The method of claim 16 wherein the controller unit is configured to determine the given location on the DUT when a respective voltage signal has a threshold signal value in the plurality of voltage signals; and wherein the controller unit is configured to generate an indication based upon a respective voltage signal in the plurality of voltage signals.

18. The method of claim 16 wherein the controller unit is configured to set a current of the AC current source signal based upon a resistance between the at least one drive electrode and the at least one sensing electrode.

19. The method of claim 16 wherein the controller unit is configured to set a current of the AC current source signal so that a voltage drop across the at least one drive electrode and the at least one sensing electrode is less than 0.1 Volt.

20. The method of claim 16 wherein the controller unit is configured to set a current of the AC current source signal in a range of 0.2-20 mA; wherein the AC current source signal has a frequency in a range of 1-3 Hz.
